(19) United States
(12) Patent Application Publication
(10) Pub. No.: US 2019/0144714 A1
(43) Pub. Date: May 16, 2019

(54) DISPLAY MODULE AND COATING GLUE METHOD THEREOF AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Niu HU, Shenzhen, Guangdong (CN)

(21) Appl. No.: 15/744,500

(22) PCT Filed: Dec. 22, 2017
(86) PCT No.: PCT/CN2017/118033

§ 371 Date: Jan. 12, 2018

(30) Foreign Application Priority Data
Nov. 10, 2017 (CN) 201711104122.5

(51) Int. Cl. C09J 5/00; G02F 1/1333; H01L 51/00; H01L 27/32; B32B 7/12; C09J 133/04; C09J 1/00; C09J 175/04; C09J 121/00

(52) U.S. Cl. CPC C09J 5/00; C09J 2421/00; H01L 51/0097; H01L 27/32; B32B 7/12; C09J 133/04; C09J 1/00; C09J 175/04; C09J 121/00; G02F 2202/28; B32B 2457/206; C09J 2205/31; C09J 2433/00; C09J 2400/14; C09J 2475/00; G02F 1/133305

(57) ABSTRACT

A coating glue method of a display module is provided. The display module includes a flexible display panel and a cover disposed on the flexible display panel, wherein the coating glue method of the display module includes the following steps: coating a transparent glue in a non-cured state between the flexible display panel and the cover, wherein the flexible display panel and the cover include a bending portion and a non-bending portion; using a blocking curing material to cover the bending portion and the transparent glue inside the bending portion; and curing the transparent glue inside the non-bending portion. The disclosure further provides a display module and a display device including the display module. In the disclosure, the transparent glue inside the bending portion is not cured and the transparent glue inside the non-bending portion is not cured to improve the adhesion and fluidity of the display panel.

### RELATED APPLICATIONS

The present application is a National Phase of International Application Number PCT/CN2017/118033, filed Dec. 22, 2017, and claims the priority of China Application No. 201711104122.5, filed Nov. 10, 2017.

### FIELD OF THE DISCLOSURE

The disclosure relates to a display module, a coating glue method thereof and a display device.

### BACKGROUND

With the development of display panel technology, flexible display panel display technology has been rapidly developed in recent years, flexible display panel has a better flexibility and a thin thickness. Besides, the performance of the adhesion of transparent glue during the bending process is particularly important. The flexibility of the flexible display panel could be improved by optimizing the properties of the transparent glue.

The traditional transparent glue needs a good optical property and a strong adhesion property and a good ink gap adsorption capacity. However, in addition to the traditional application requirements, the transparent glue applied on the flexible display panel needs a better bending resistance that could relieve and release the stress generated during bending other layers. But the flexible display panel obviously has bending failure and non-recoverable deformation problems in the prior art.

### SUMMARY

A technical problem to be solved by the disclosure is to provide a display module, a coating glue method thereof and a display device.

Furthermore, the disclosure further provides a display device including the display panel.

To achieve the above object, according to one aspect, the embodiment of the disclosure provides a coating glue method of a display module, the display module including a flexible display panel and a cover disposed on the flexible display panel, wherein the coating glue method of the display module includes the following steps:

coating a transparent glue in a non-cured state between the flexible display panel and the cover, wherein the flexible display panel and the cover include a bending portion and a non-bending portion;

using a blocking curing material to cover the bending portion and the transparent glue inside the bending portion; and

curing the transparent glue inside the non-bending portion.

Wherein the coating glue method of the display module further includes the following steps: removing the blocking curing material on the bending portion after curing the transparent glue inside the non-bending portion.

Wherein the blocking curing material is an ultraviolet blocking material.

Wherein the step of curing the transparent glue inside the non-bending portion specifically is: performing an ultraviolet curing method to cure the transparent glue inside the non-bending portion.

Wherein a radius of the bending portion is R, a length of the bending portion is πR, and a length of the non-bending portion is between πR+5 and πR+10.

Wherein a material of the transparent glue is one or a combination of acrylic, silicon, polyurethane and rubber.

Wherein the bending portion is a middle position of the flexible display panel and the cover, the non-bending portion is located at two sides of the bending portion.

The disclosure further provides a display module, the display module includes a flexible display panel, a cover disposed on the flexible display panel and a transparent glue disposed between the flexible display panel and the cover, wherein the flexible display panel and the cover include a bending portion and a non-bending portion, the transparent glue inside the bending portion is not cured and the transparent glue inside the non-bending portion is not cured.

Wherein a radius of the bending portion is R, a length of the bending portion is πR, and a length of the non-bending portion is between πR+5 and πR+10.

The disclosure further provides a display device, the display device includes the above-mentioned display module.

The display device, the display module and the coating glue method thereof provided by the disclosure cures the transparent glue inside the non-bending portion to improve the adhesion of the transparent glue, and does not cure the transparent glue inside the bending portion to provide the fluidity of the transparent glue.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts.

FIG. 1 is a module schematic view of a display device according to an embodiment of the disclosure;

FIG. 2 is a schematic view of a display module after bending according to an embodiment of the disclosure;

FIG. 3 is a schematic view of a display module including a bending portion and a non-bending portion according to an embodiment of the disclosure;

FIG. 4 is a flow chart diagram of a coating glue method of a display module according to an embodiment of the disclosure.

### DETAILED DESCRIPTION OF PREFERRED EMBODIMENTS

In order to illustrate a technical solution according to embodiments of the disclosure more clearly, drawings to be used in the description of the embodiments will be briefly set forth in the following. It is obvious that the drawings in the following description are only related to some embodiments of the disclosure. Those ordinarily skilled in the art may obtain other embodiments according to these drawings, without any inventive work.

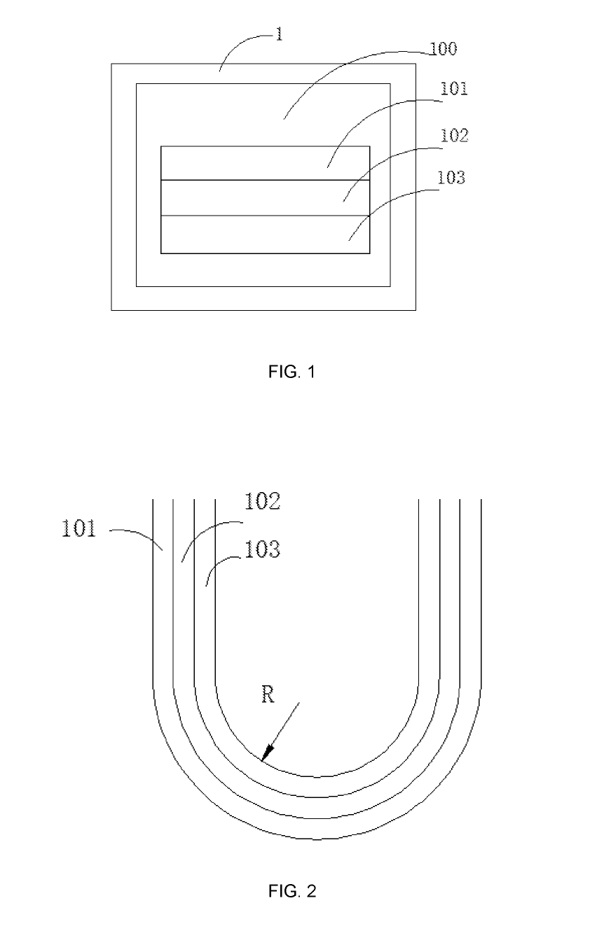

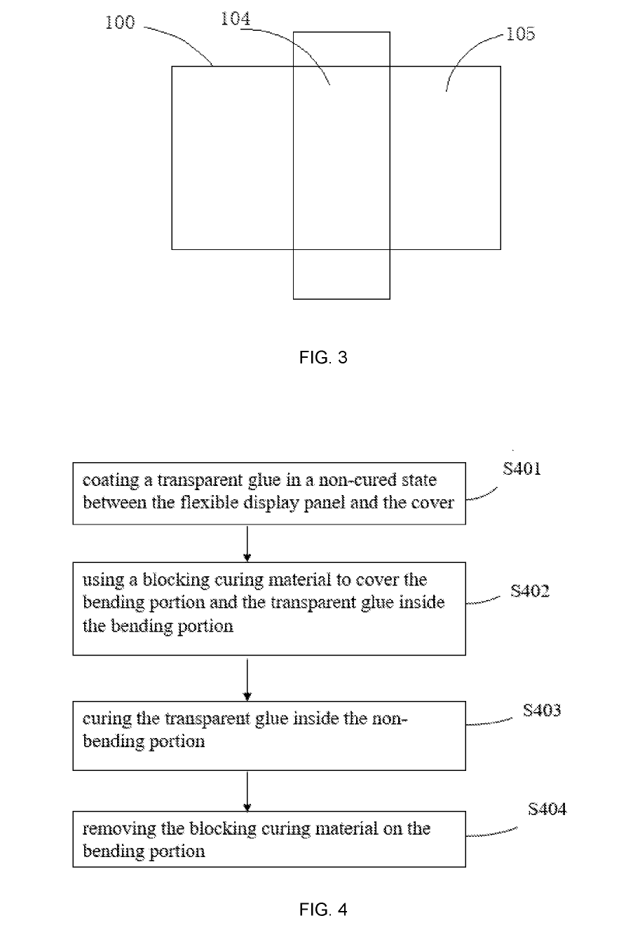

As shown in FIG. 1 to FIG. 3, are schematic views of a display device according to an embodiment of the disclosure. In this embodiment, the display device 1 could be liquid crystal display, liquid crystal television, mobile phone or tablet and so on. The display device 1 includes a display module 100. The display module 100 includes a flexible display panel 103, a cover 101 disposed on the flexible display panel 103 and a transparent glue 102 disposed between the flexible display panel 103 and the cover 101. In this embodiment, the flexible display panel 103 is a display panel made of organic light emitting diodes. In other embodiment, the flexible display panel 103 could be a liquid crystal display panel and so on. The flexible display panel 103 and the cover 101 include a bending portion 104 and a non-bending portion 105. In this embodiment, the bending portion 104 is defined as a bendable part, a radius of the bending portion 104 is R and a length of the bending portion 104 is πR in the bending state, and a length of the non-bending portion 105 is between πR+5 and πR+10. The transparent glue 102 inside the bending portion 104 is not cured, so the transparent glue 102 of the display module 100 has better fluidity when bending along the bending portion 104. The transparent glue 102 inside the non-bending portion 105 is not cured, so the display module 100 has better adhesion performance in the non-bending portion 105. Therefore, the display module bending failure and non-recoverable deformation problems could be solved.

In this embodiment, the flexible display panel 103 and the cover 101 are bending along a middle position, so the bending portion 104 is the middle position of the flexible display panel 103 and the cover 101, the non-bending portion 105 is located at two sides of the bending portion 104. In other embodiment, the flexible display panel 103 and the cover 101 could bend along a predetermined position, so the bending portion 104 and the non-bending portion 105 could be correspondingly disposed according to the predetermined position.

As shown in FIG. 4, a coating glue method of a display module provided by the disclosure, including the following steps:

Step S401, coating a transparent glue 102 in a non-cured state between the flexible display panel 103 and the cover 101. In this embodiment, a material of the transparent glue 102 is one or a combination of acrylic, silicon, polyurethane and rubber.

Step S402, using a blocking curing material to cover the bending portion 104 and the transparent glue 102 inside the bending portion 104.

Step S403, curing the transparent glue 102 inside the non-bending portion 105. In this embodiment, the blocking curing material is an ultraviolet blocking material, the step of curing the transparent glue 102 inside the non-bending portion 105 specifically is: performing an ultraviolet curing method to cure the transparent glue 102 inside the non-bending portion 105. In other embodiment, the blocking curing material could be other material depending on the curing method, other curing method such as moisture curing, heat curing, anaerobic curing and double curing and so on.

Furthermore, the coating glue method of the display module further includes the following steps: removing the blocking curing material on the bending portion 104 after curing the transparent glue 102 inside the non-bending portion 105.

In the display device and the display module provided by the disclosure, the transparent glue inside the bending portion is not cured, and the transparent glue inside the non-bending portion is not cured, so the display module bending failure and non-recoverable deformation problems could be solved.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A coating glue method of a display module, the display module comprising a flexible display panel and a cover disposed on the flexible display panel, wherein the coating glue method of the display module comprises the following steps:
coating a transparent glue in a non-cured state between the flexible display panel and the cover, wherein the flexible display panel and the cover include a bending portion and a non-bending portion;
using a blocking curing material to cover the bending portion and the transparent glue inside the bending portion; and
curing the transparent glue inside the non-bending portion.

2. The coating glue method of a display module according to claim 1, wherein the coating glue method of the display module further comprises the following steps: removing the blocking curing material on the bending portion after curing the transparent glue inside the non-bending portion.

3. The coating glue method of a display module according to claim 1, wherein the blocking curing material is an ultraviolet blocking material.

4. The coating glue method of a display module according to claim 2, wherein the step of curing the transparent glue inside the non-bending portion specifically is: performing an ultraviolet curing method to cure the transparent glue inside the non-bending portion.

5. The coating glue method of a display module according to claim 1, wherein a radius of the bending portion is R, a length of the bending portion is πR, and a length of the non-bending portion is between πR+5 and πR+10.

6. The coating glue method of a display module according to claim 1, wherein a material of the transparent glue is one or a combination of acrylic, silicon, polyurethane and rubber.

7. The coating glue method of a display module according to claim 1, wherein the bending portion is a middle position of the flexible display panel and the cover, the non-bending portion is located at two sides of the bending portion.

8. A display module, comprising a flexible display panel, a cover disposed on the flexible display panel and a transparent glue disposed between the flexible display panel and the cover, wherein the flexible display panel and the cover include a bending portion and a non-bending portion, the transparent glue inside the bending portion is not cured and the transparent glue inside the non-bending portion is not cured.

9. The display module according to claim 8, wherein a radius of the bending portion is R, a length of the bending portion is πR, and a length of the non-bending portion is between πR+5 and πR+10.

10. A display device, comprising a display module, the display module comprising a flexible display panel, a cover disposed on the flexible display panel and a transparent glue disposed between the flexible display panel and the cover, wherein the flexible display panel and the cover include a bending portion and a non-bending portion, the transparent glue inside the bending portion is not cured and the transparent glue inside the non-bending portion is not cured.

11. The display device according to claim 10, wherein a radius of the bending portion is R, a length of the bending portion is πR, and a length of the non-bending portion is between πR+5 and πR+10.
